(19) United States
(12) Patent Application Publication
(10) Pub. No.: US 2003/0160319 A1
(43) Pub. Date: Aug. 28, 2003

(54) Solid assembly of flip-chip package attached to heat removal device and method of manufacturing same

(76) Inventors: Wen-Chun Zheng, San Jose, CA (US); Henry H. Jung, Cupertino, CA (US)

Correspondence Address: ROSENTHAL & OSHA L.L.P. / SUN, 1221 MCKINNEY, SUITE 2800, HOUSTON, TX, 77010, US

(21) Appl. No.: 10/085,183

(22) Filed: Feb. 27, 2002

(51) Int. Cl. H01L 23/34

(52) U.S. Cl. 257/712; 257/717; 257/722

(57) ABSTRACT

A flip-chip package assembly having a package substrate having a mounting surface to which a semiconductor die and a heat removal device is selectively mounted is provided. The flip-chip assembly is made out of a package substrate on which a semiconductor die is positioned and a heat removal device which is physically secured to the package substrate. The semiconductor die is thermally connected to the heat removal device through a thermal interface material. Further, a method for manufacturing the flip-chip package described herein is disclosed.

### FIELD OF THE INVENTION

The invention relates to packaging of semiconductor devices.

### BACKGROUND OF THE INVENTION

Thermal management of semiconductor devices has become an increasing concern as operation speeds increase and space (particularly for portable applications) decreases. Demand for ever-faster microprocessors results in the need to dissipate larger and larger amounts of heat. Accordingly, thermally efficient packaging of semiconductor devices have become critical to further advances in semiconductor device design.

FIG. 1 is a schematic side view of a prior art package assembly for semiconductor device. In this configuration, which is known as a “flip-chip” package, the active device, here shown as semiconductor die 11, is inverted so that the inactive side of the die is facing away from the package substrate 13. An advantage of this configuration is that it facilitates heat dissipation through the back of the semiconductor die 11 directly to a heat removal device such as a heat sink.

The active side of the semiconductor device in the flip-chip package is connected to the package substrate via any one of a number of conventional methods. In the example shown, the connection method is via a plurality of solder balls 14 in what is known in the industry as a ball grid array (BGA). Other known connection mechanisms include a pin grid array (PGA), a land grid array (LGA), a plastic pin array (PPGA), and a ceramic pin grid array (CPGA).

It is common for the area of the top of the package substrate 13 to surrounding the semiconductor die 11 to be used as a mounting location for high frequency capacitors, shown in the figure as capacitors 17. These capacitors may be mounted in a BGA configuration, or by any other known connection mechanism. FIG. 2 illustrates the prior art flip-chip package assembly shown in FIG. 1 in top view. In this view, for the sake of example, four capacitors 17 are shown.

FIG. 3 shows a perspective view of a flip-chip package mounted in a socket on a printed circuit board (PCB). In this figure, the package assembly including the package substrate 13, semiconductor die 11, and capacitors 17 are shown engaged in socket 19, which in turn is mounted on printed circuit board 20. Also mounted on PCB 20 are various typical electronic components including, for example, low frequency capacitors 21, transistors 23, and air core inductor 25.

### SUMMARY OF INVENTION

According to one aspect of the present invention, a flip-chip package assembly comprises a package substrate having a mounting surface, a semiconductor die mounted on a first portion of the mounting surface, a heat removal device physically secured to a second portion of the mounting surface; and a thermal interface material disposed between the semiconductor die and the heat removal device.

According to another aspect, a method for manufacturing a flip-chip package assembly, where the flip-chip package assembly comprises a package substrate and a semiconductor die, comprises disposing the semiconductor die on a first portion of a mounting surface of the package substrate, physically securing a heat removal device to a second portion of the mounting surface, and disposing a thermal interface material between the heat removal device and the semiconductor die.

According to another aspect, a flip-chip package assembly comprises supporting means for providing support to a semiconductor die, heat removal means for dissipating heat from the semiconductor die, interfacing means for transferring heat from the semiconductor die to the heat removal means, and attaching means for attaching the heat removal means to the supporting means.

Other aspect and advantages of the invention will be apparent from the following description and the appended claims.

### BRIEF DESCRIPTION OF DRAWINGS

FIG. 1 is a side view of a prior art flip-chip package assembly;

FIG. 2 is a top view of the assembly of FIG. 1;

FIG. 3 is a perspective view of a typical flip-chip installation on a printed circuit board;

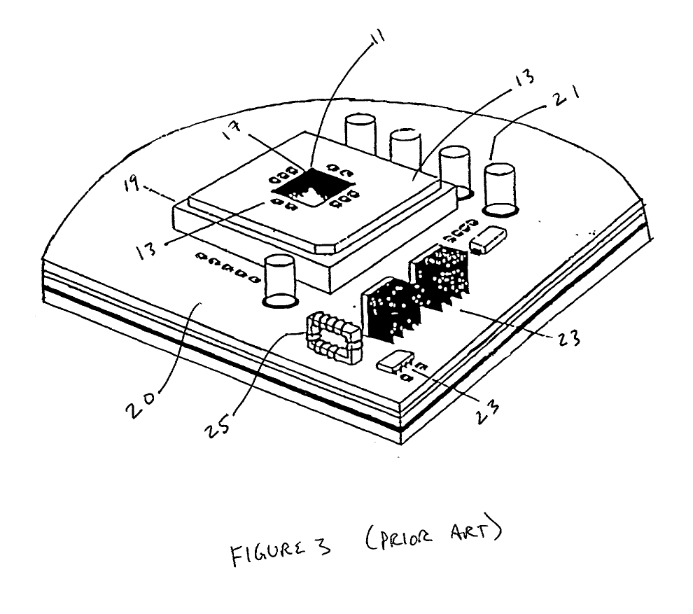

FIG. 4 is a cross sectional view of a flip-chip package assembly with a heat sink;

FIG. 5 is a bottom view of a heat sink in accordance with one embodiment of the invention;

FIG. 6 is a bottom view of a heat sink in accordance with another embodiment of the invention;

FIG. 7 is a cross sectional view of a flip-chip package assembly with a heat sink in accordance with an embodiment of the invention.

FIG. 8 is a flowchart of a manufacturing method in accordance with an embodiment of the invention.

### DETAILED DESCRIPTION

Various exemplary embodiments of the invention will now be described with reference to the accompanying figures. Like elements are referred to by like reference numerals in the several views for the sake of clarity.

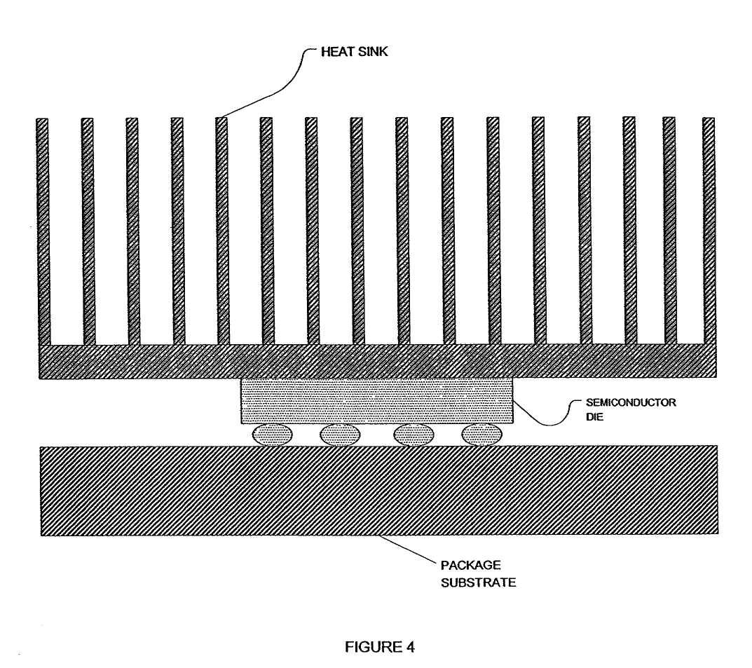

Referring now to FIG. 4, a semiconductor die 11 mounted a first portion of the mounting surface of the package substrate 13 is shown. Throughout this disclosure, the BGA configuration is used as an example. However, this is for installation purposes only and shall be considered generic to any of the known or later-discovered mechanisms for flip-chip attachment. To facilitate heat removal from the die, a heat sink 27 is provided adjacent the top, inactive side of the die 11. At an interface 29 between the die 11 and the heat sink 27, various approaches may be taken for securing the heat sink to the die and for promoting thermal transfer therebetween. These approaches include solder, thermal interface material such as tape, phase change material, thermal grease, etc. For ease of illustration, FIG. 4 is not to scale; however, it should be understood that the heat sink 27 would normally extend horizontally beyond the package substrate 13 in all directions. Thus, in addition to the problem of making the heat transfer from the die to the heat sink as efficient as possible, there is the mechanical issue of securing the large heat sink to the much smaller die in a robust fashion. Particularly in portable applications where significant stresses may be encountered, an insufficient mechanical connection may result in displacement of the heat sink 27, while a rigid connection may result in stress or even irreparable damage to the die itself. In applications where thermal grease or phase change material is used as the heat transfer material at interface 29, it is conventionally necessary to provide a physical attachment between the heat sink 27 and the printed circuit board to provide a secure mechanical connection. Such a connection is not shown in FIG. 4, but may take various conventional forms such as, for example, pins or screws extending from the heat sink 27 to the printed circuit board. Regardless of the attachment mechanism, conventional approaches typically require that the heat sink 27 be installed on the flip-chip assembly at the time of system assembly (as opposed to flip-chip package assembly), thus adding additional steps and possibilities for error at the system assembly level. The common errors are package/socket misalignment and thick interface material. A thick interface material will degrade thermal performance. For example, in a high-power CPU package, even a 0.01° C./w reduction will lose a 1° C. margin.

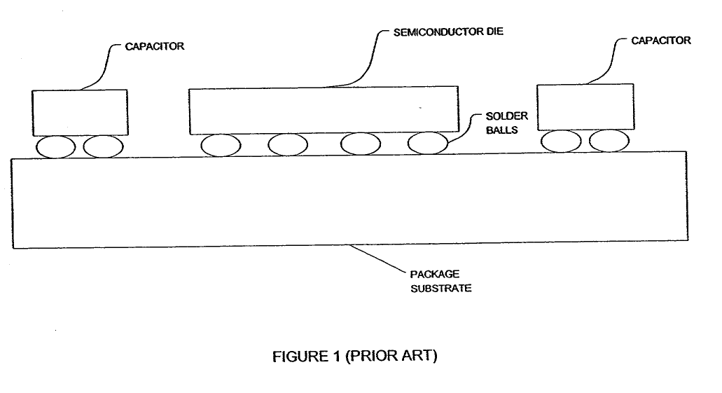

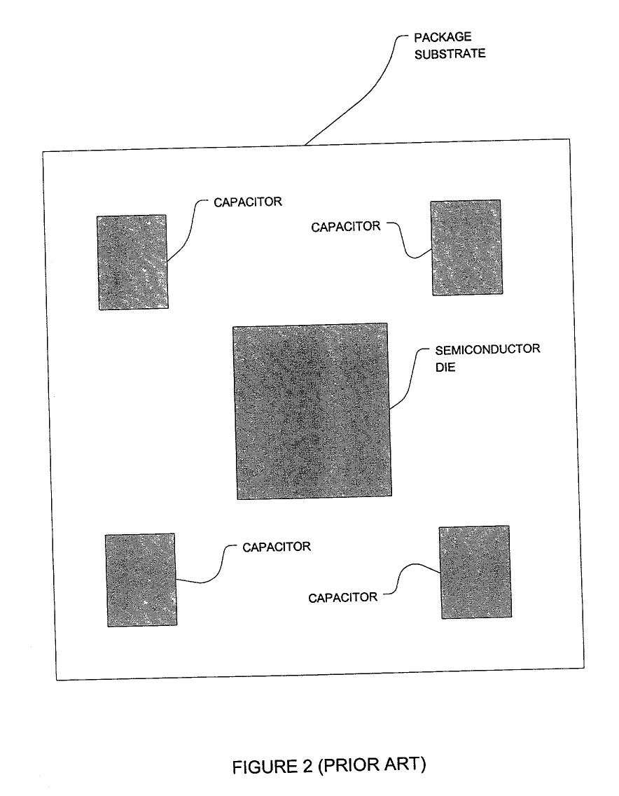

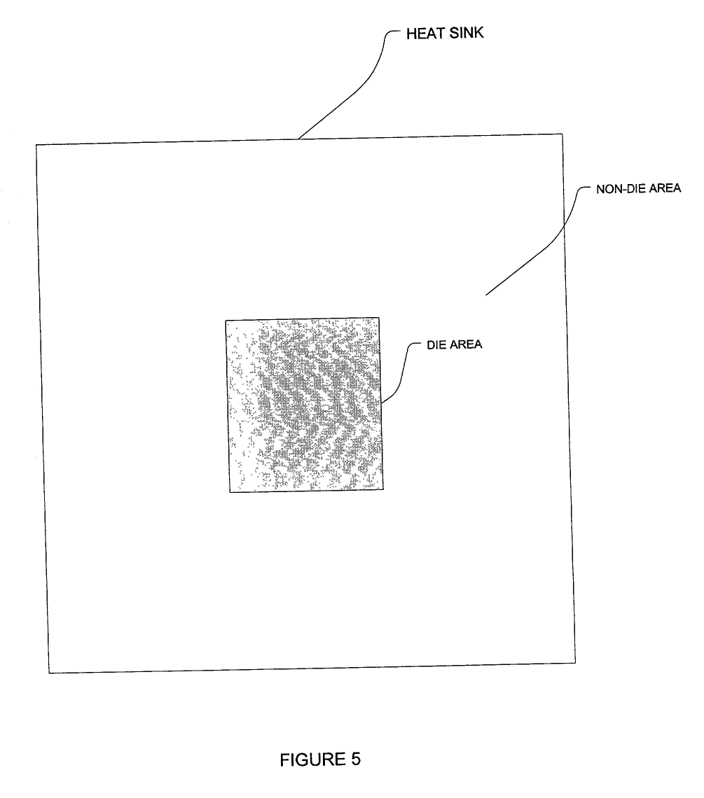

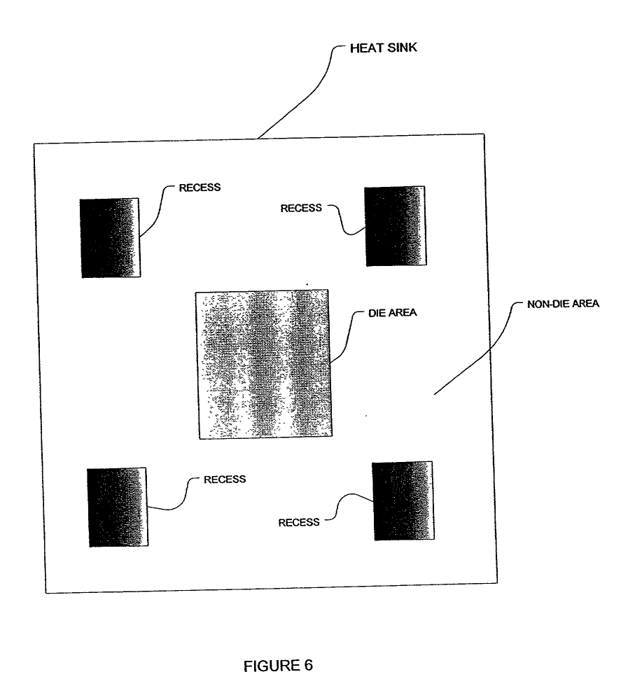

FIG. 5 is a bottom view of a heat sink 27. The bottom side 30 of the heat sink 27 may be divided into a die area 31 (i.e., the area that will be adjacent the die) and a non-die area 33 (i.e., the area of the bottom surface 30 that will extend beyond the die). At least a portion of the non-die area 33 will extend over the package substrate 13. This area (which does not include die area 31), shall be referred to herein as package area 35. In some embodiments, depending upon the profile of the semiconductor die 11 (i.e., the height of the die above the package substrate 13, shown as distance D in FIG. 4), it may be desirable to recess the die area 31 to allow the package area 35 to be in closer proximity to the package substrate 13. In addition, referring back to FIGS. 1 and 2, it is common for one or more high frequency capacitors 17 to be mounted on the package substrate 13 in the area around the semiconductor die. Although the vertical profile of the semiconductor die 11 and capacitors 17 are shown to be the same in FIG. 1, the vertical profile of a capacitor 17 may in fact be less than or greater than that of semiconductor die 11. Therefore, in accordance with the embodiment of FIG. 6, a plurality of recesses 37 also may be formed in the package area 35 in locations corresponding to the capacitors 17. The invention is intended to encompass a flat bottom surface 30 of the heat sink 27, as well as any combination of a recessed die area 31 and one or more recesses 37 for capacitors or other components mounted on the package substrate 13.

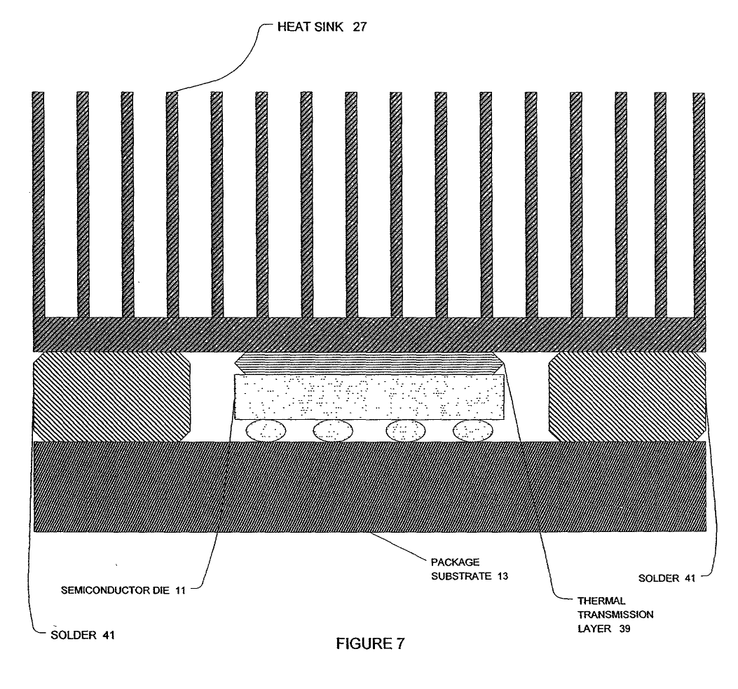

In accordance with the invention, it has been recognized that it would be desirable from a system assembly standpoint for the flip-chip package and heat sink to be constructed as a solid assembly. This solid assembly then can simply be mounted in the socket 19 on the circuit board 20. This avoids the need for additional steps such as placing sensitive material in the region 29 between the heat sink 27 and the die 11, and making other mechanical interconnections between the heat sink 27 and PCB 20. In accordance with this recognition, the invention provides a solid assembly for a flip-chip package including a heat sink (or other heat removal device) that achieves efficient thermal transfer from the die to the heat sink while providing a secure mechanical connection between the heat sink and the package substrate. Particularly, referring now to FIG. 7, a thermal interface material 39 is provided between the die 11 and the heat sink 27 to facilitate transfer of heat from the die to the heat sink. The choice of the material to be used for the thermal interface material 39 depends upon the design parameters of the particular semiconductor device being used as well as the intended application (e.g., portable versus stationary). However, importantly, the thermal interface material 39 need not provide any mechanical connection between the die and the heat sink, thus avoiding the possibility of damaging to the die due to the stresses caused by the heat sink 27. Also, because the function as a mechanical inter-connector has been avoided, the thermal interface material 39 can be maintained as a thin layer. Preferably, the material should not be a pressure-sensitive material. Typical materials that may be used for thermal interface material 39 include, but are not limited to, low melt solder, phase change material, thermal interface material such as tape, etc.

In order to provide a mechanical connection between the second portion of the package substrate 13 and the heat sink 27, and thereby produce a solid assembly of a flip-chip package and a heat sink or other heat removal device, adhesive material is used in some or all of package area 35 to provide the necessary structural rigidity. The adhesive material 41 may be any type of known adhesive material, e.g., eutectic solder paste, or other adhesives. In some embodiments, all of package area 35 surrounding die area 31 (and excluding any recesses 37) is coated with adhesive material 41. The standoff of adhesive material 41 is greater than that of thermal interface material 39. Generally, it is desirable that thermal layer 39 be as thin as possible so as to promote maximum heat transfer.

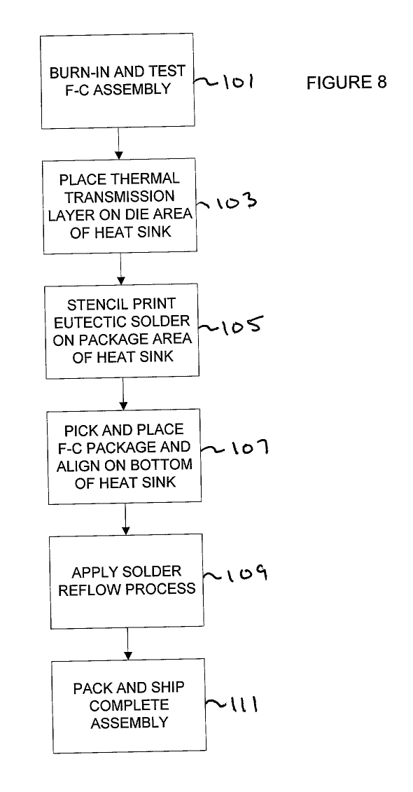

Referring now to FIG. 8, a flow chart is shown illustrating an embodiment of a method of manufacturing a solid assembly of a flip-chip package and a heat removal device. In this embodiment, for purposes of illustration, the adhesive material is eutectic solder paste. First, in step 101, a conventional flip-chip assembly is subjected to conventional burn-in and test procedures. Next, in step 103, a thermal interface material is placed on the die area of the heat sink. In the case of low melting temperature solder, the solder is stencil printed on the die area of the heat sink at minimum thickness. For other thermal transmission materials, such as phase change material, thermal tape, thermal grease, etc., these materials are applied to the die area in accordance with normal procedures.

It should be understood that if the die area 31 has been recessed, the effective standoff of the die is the actual standoff (D in FIG. 4), less the amount of the recess. In addition, it should be understood that the eutectic solder would normally not be provided in any recessed area such as recesses 37 formed in package area 35. Moreover, the eutectic solder may be placed over the entire package area 35, or simply at certain discrete locations thereof, depending upon the particular design considerations involved.

In step 105, the eutectic solder is stencil printed on the package area of the heat sink. In step 107, the flip-chip package is picked up and placed in inverted fashion on the bottom of the heat sink so as to be aligned with the die area 31. Subsequently, in step 109, a solder reflow process is applied to effect the solder connection between the package substrate and the heat sink. Finally, after the assembly has cooled, the completed assembly is packed and shipped (step 111).

The various embodiments to the invention provide one of more of the following advantages. A solid assembly of a flip-chip package attached to a heat sink or other heat removal device is provided. Thus, these elements that were conventionally assembled during the system assembly process may now, in accordance with the invention, be shipped as a single unit and simply plugged into the socket on the printed circuit board. Thus, substantial savings in terms of time and difficulty during system assembly may be achieved. Moreover, the invention provides a solid assembly where structural connection between the heat sink and the package substrate is maintained, without allowing excessive forces to be placed on the die. Accordingly, the material used for the thermal interface material 39 may be chosen depending upon the operational characteristics of the semiconductor device and its intended application, rather than purely based on the need for mechanical interconnection between the die and the heat sink.

Various exemplary embodiments of the invention have been shown and described above. However, the invention is not so limited. Rather, the invention shall be considered limited only by the scope of the appended claims.

What is claimed is:

1. A flip-chip package assembly comprising:
a package substrate having a mounting surface;
a semiconductor die mounted on a first portion of the mounting surface;
a heat removal device physically secured to a second portion of the mounting surface; and
a thermal interface material disposed between the semiconductor die and the heat removal device.

2. The flip-chip package assembly according to claim 1, wherein the heat removal device is a heat sink.

3. The flip-chip package assembly according to claim 1, wherein the heat removal device is physically secured to the second portion of the mounting surface by an adhesive.

4. The flip-chip package assembly according to claim 3, wherein the adhesive is disposed at a plurality of discrete locations on the second portion of the mounting surface.

5. The flip-chip package assembly according to claim 3, wherein the adhesive comprises eutectic solder paste.

6. The flip-chip package assembly according to claim 1, wherein the thermal interface material is selected from the group consisting of low melt solder phase change material, thermal tape and thermal grease.

7. The flip-chip package assembly according to claim 1, wherein a bottom surface of the heat removal device comprises at least one recess for accommodating the semiconductor die.

8. The flip-chip package assembly according to claim 7, wherein the bottom surface of the heat removal device further comprises at least one recess for accommodating at least one electrical component mounted on the second portion of the mounting surface

9. A method for manufacturing a flip-chip package assembly comprising a package substrate and a semiconductor die, the method comprising:
disposing the semiconductor die on a first portion of a mounting surface of the package substrate;
physically securing a heat removal device to a second portion of the mounting surface; and
disposing a thermal interface material between the heat removal device and the semiconductor die.

10. The method according to claim 9, wherein the heat removal device is a heat sink.

11. The method according to claim 9, wherein physically securing the heat removal device comprises disposing an adhesive between the heat removal device and the second portion of the mounting surface.

12. The method according to claim 11, wherein the adhesive is disposed at discrete locations between the heat removal device and the second portion of the mounting surface.

13. The method according to claim 12, wherein the adhesive is eutectic solder paste.

14. The method according to claim 9, wherein the thermal interface material is selected from the group consisting of low melt solder phase change material, thermal tape and thermal grease.

15. The method according to claim 9, wherein a bottom surface of the heat removal device comprises at least one recess for accommodating the semiconductor die.

16. The method according to claim 15, wherein the bottom surface of the heat removal device further comprises at least one recess for accommodating at least an electrical component mounted on the second portion of the mounting surface.

17. A flip-chip package assembly, comprising:
supporting means for providing support to a semiconductor die;
heat removal means for dissipating heat from the semiconductor die;
interfacing means for transferring heat from the semiconductor die to the heat removal means; and
attaching means for attaching the heat removal means to the supporting means.
